(19) United States
(12) Patent Application Publication
(10) Pub. No.: US 2018/0337140 A1
(43) Pub. Date: Nov. 22, 2018

(54) 3D INTEGRATED CIRCUIT DEVICE HAVING A BUTTRESS STRUCTURE FOR RESISTING DEFORMATION

(71) Applicant: MACRONIX INTERNATIONAL CO., LTD., Hsinchu (TW)

(72) Inventors: Tuung Luoh, TAIPEI (TW); Yung-Tai Hung, CHIAYI (TW); Ta-Hung Yang, MIAOLI (TW); Kuang-Chao Chen, HSINCHU (TW)

(73) Assignee: MACRONIX INTERNATIONAL CO., LTD., HSINCHU (TW)

(21) Appl. No.: 15/602,019

(22) Filed: May 22, 2017

(51) Int. Cl. H01L 23/00; H01L 27/1157; H01L 27/11582; H01L 27/11565; H01L 27/11573; H01L 23/58

(52) U.S. Cl. CPC H01L 23/562; H01L 27/1157; H01L 23/585; H01L 27/11565; H01L 27/11573; H01L 27/11582

(57) ABSTRACT

An integrated circuit includes a stack in a stack region and a region outside the stack region. A buttress structure disposed outside the stack includes a fence-shaped, electrically passive element configured to oppose expansion of materials outside the stack region in a direction toward the stack region.

### BACKGROUND

### Field of the Technology

The present technology relates to high density integrated circuit devices, including three-dimensional 3D memory devices, which can be subject to deformation stress during manufacturing.

### Description of Related Art

3D integrated circuits comprise stacks of material having multiple planes of circuit elements disposed in a stack. For example, technologies for stacking multiple levels of memory cells to achieve greater storage capacity have been developed. Researchers have developed various structures, such as Bit Cost Scalable (BiCS) memory, Terabit Cell Array Transistor (TCAT) and Vertical NAND (V-NAND). For these types of structures, and other complex structures that comprise stacks of active layers separated by insulating (or inactive) layers, it is often useful to form conductors or other circuit elements connecting layers deep in the stacks with upper layers or with patterned metal layers over the stacks used for connection to peripheral circuits.

However, the formation of these conductors or other circuit elements can be difficult. Once the stack is etched to define patterns in an intermediate structure which can include high aspect ratio trenches, the intermediate structure tends to deform as a result of manufacturing processes or environments.

FIG. 1 is a simplified illustration of a three-dimensional (3D) NAND non-volatile memory device, in which has a stack of alternating conductive layers (e.g. 111, 113, 115, 117) and insulating layers (e.g. 110, 112, 116, 118) on a substrate 100, and a plurality of memory pillars (e.g. 130-137) and a plurality of high aspect ratio trenches (e.g. 120, 121, 122, 123) in the stack. As seen in FIG. 1, the stack is deformed due to, for example, stress caused by thermal expansion of surrounding structures or other stresses. Such deformation increases the difficulty of filling the trenches.

FIG. 2 is a simplified illustration of a three-dimensional (3D) NAND non-volatile memory device, in which the conductors (e.g. 201, 202, 203, 204) in the trenches are deformed due to the stress induced by the deposition of conductors. The deformation formed either before or after filling the trenches would cause changes in the locations of the pillars and conductive lines. These changes in position can cause alignment problems with upper layer structures, and lead to misconnection to and/or misalignment of patterned conductor layers implemented over the stack, typically in back-end-of-line (BEOL) routings.

It is desirable to provide a 3D integrated circuit structure with reduced deformation. This can improve the quality of circuit elements extending through or into the stacks, and improve alignment tolerances for the BEOL routings and other structures.

### SUMMARY

A process for making a buttress structure and the resulting structure are described, which can oppose stress-induced deformation of the device being formed.

In one aspect, an integrated circuit described herein comprises a stack region and a region outside the stack region over a substrate; a stack including a plurality of layers disposed in the stack region; a plurality of circuit elements extending through the stack; and a buttress structure disposed around the stack region, the buttress structure comprising a fence-shaped, electrically passive element configured to oppose expansion of materials in the region outside the stack region in a direction toward the stack region.

In another aspect, a method of manufacturing an integrated circuit described herein comprises forming a stack including a plurality of layers in a stack region on a substrate; forming a buttress structure around the stack; etching through the plurality of layers in the stack to form a pattern of openings in the stack, after forming the buttress structure; and filling at least some of the openings in the stack with conductive or semiconductive material to form circuit elements in the stack.

In yet another aspect, an integrated circuit described herein comprises a stack of active and inactive layers disposed over a substrate; a plurality of vertical conductors extending through the stack of active and inactive layers; and a region surrounding the stack including a buttress structure in a fill material, wherein the buttress structure comprises a material having a Young's modulus greater than the fill material.

Other aspects and advantages of the present technology can be seen on review of the drawings, the detailed description and the claims, which follow.

### BRIEF DESCRIPTION OF THE DRAWINGS

FIG. 1 is a simplified illustration of a deformed 3D NAND non-volatile memory device before formation of filled-trench vertical conductors.

FIG. 2 is a simplified illustration of a deformed 3D NAND non-volatile memory device after formation of filled-trench vertical conductors.

FIG. 3 is a heuristic layout illustrating a 3D memory device in one embodiment.

FIG. 4 illustrates various configurations of the buttress structure as described herein.

FIGS. 5-9 are cross-sectional views illustrating structures during manufacturing stages for a 3D NAND memory in one embodiment as described herein.

FIGS. 10A-10D illustrate a simplified cross-sectional view of a 3D stack with circuit elements extending through the layers of the stack, such as used in a memory array like that of FIG. 9, and alternative cross-sectional shapes of elements of the buttress structure.

FIGS. 11A and 11B are graphs showing the ANSYS simulation results for 3D memories without and with the buttress structure, respectively (ANSYS computer simulation tool provided by ANSYS, Inc.).

FIG. 11C is a table showing the parameters for different materials applied to the ANSYS simulations of FIGS. 11A and 11B.

FIG. 12 is a bar chart illustrating the displacement as a function of the depth of the buttress structure.

FIG. 13 is a block diagram of an integrated circuit memory including a 3D memory array having the buttress structure as described herein.

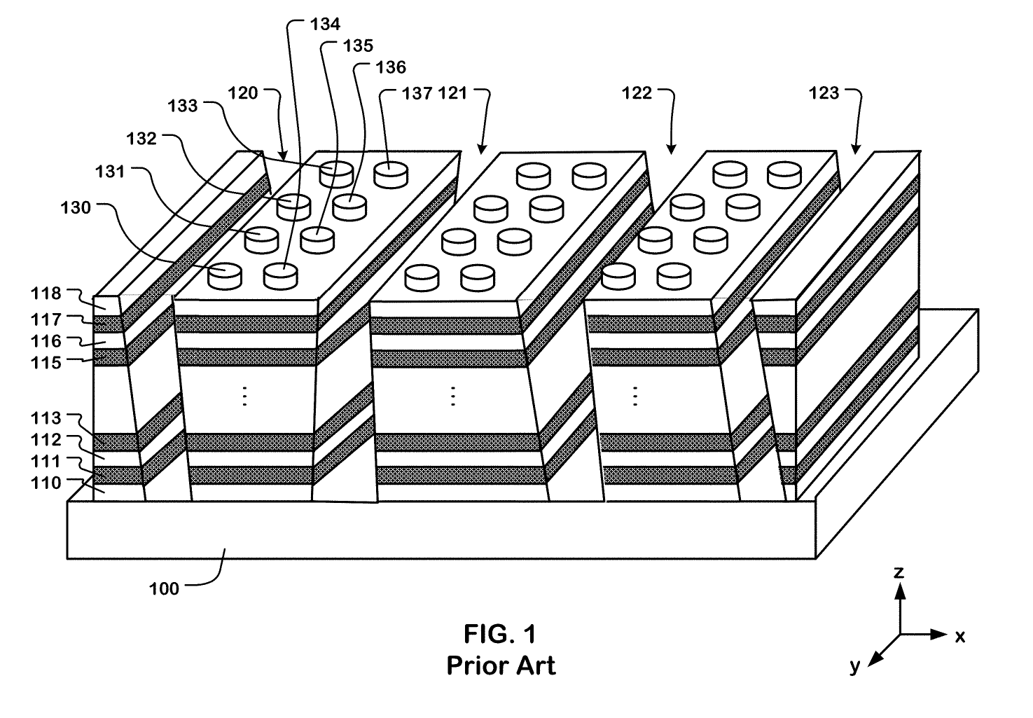

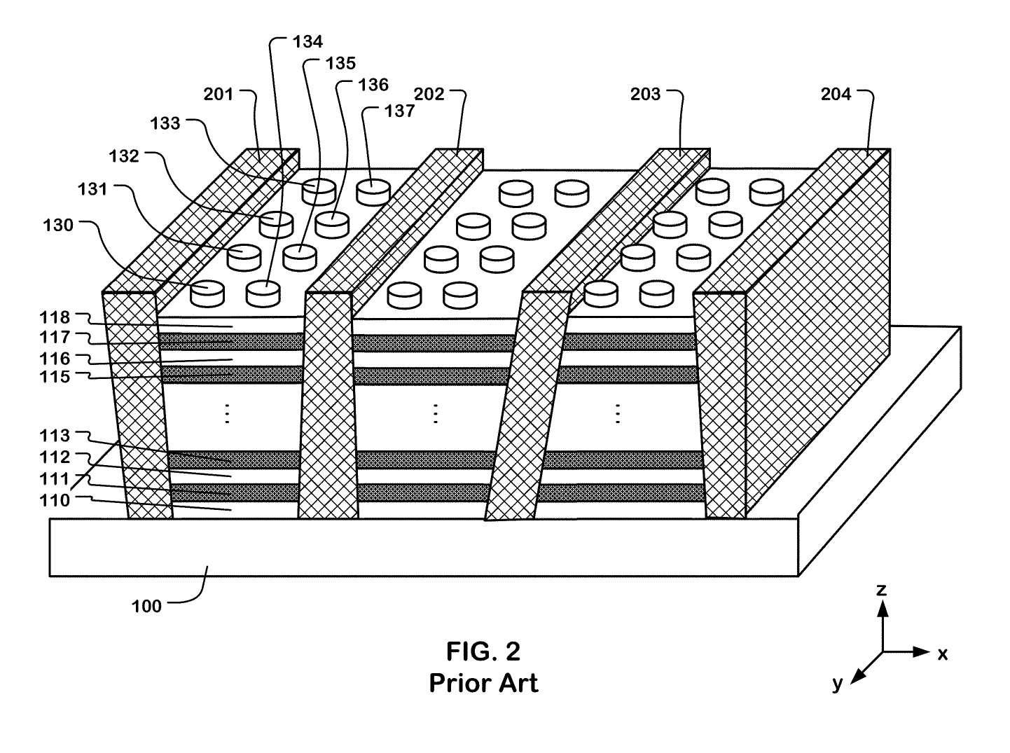

### DETAILED DESCRIPTION

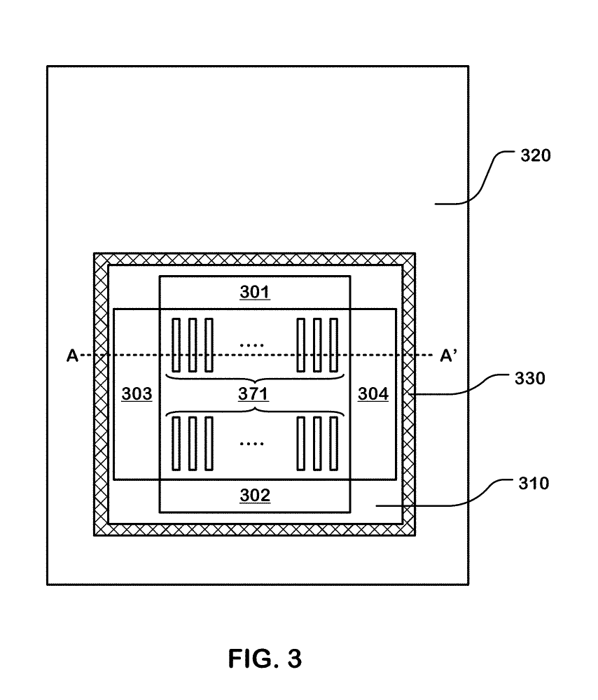

A detailed description of embodiments of the present invention is provided with reference to FIGS. 3-10.

FIG. 3 is a heuristic layout illustrating an integrated circuit device which comprises a stack region 310 and a region 320 outside the stack region 310 over a substrate. A stack includes a plurality of layers disposed in the stack region 310. A plurality of circuit elements 371 extends through the stack. An electrical conductor (not shown) in a patterned conductor layer over the stack is connected to one or more of the circuit elements 371. The stack region 310 may comprise a plurality of stacks. The stack comprises active layers like conductors involved in the circuit functions, and inactive layers like insulators that primarily operate to electrically isolate the active layers in the stack.

Stair step structures are disposed in regions 301, 302, 303, 304 and can be configured as word line landing pads for example along the sides of the stack or stacks in this example. In another example, the stair step structures can be disposed in the other layout configurations, such as in the middle of the stack or stacks. The number and location of the stair step structures are changeable depending on the device layout and design.

A buttress structure 330 is disposed around the stack region 310 and comprises a fence-shaped, electrically passive element disposed in a fill material in a closed polygonal line surrounding the stack region. The fence-shaped, electrically passive element is configured to oppose expansion of materials in the region 320 in a direction toward the stack region 310. The fence-shaped, electrically passive element is a unitary element and has a closed rectangular shape in this example. The buttress structure 330 is electrically passive in the sense that it does not have any circuit functions. The electrically passive buttress structure 330 is isolated from the ground potential and other voltage sources. In some embodiments, the buttress structure may not be isolated, for example, but does not contribute to the electrical function of the circuit. In some embodiments, the buttress structure can extend through, or have a depth as deep as, multiple layers in the stack.

The buttress structure is disposed in an intermediate region between the stack region and structures that form peripheral circuits outside the stack region in a peripheral region. There are no conductive lines that extend through the intermediate region in which the buttress is formed from the stack to the peripheral circuits in this example. Rather all electrical connections between the circuit elements in the stack and the peripheral circuits are formed in patterned conductors over the buttress structure, or beneath the buttress structure.

The buttress structure 330 may comprise a material having a Young's modulus greater than the fill material in which it is disposed, in one embodiment. The buttress structure 330 may comprise a gap in another embodiment.

The device comprises a structure forming peripheral circuits in the region 320 outside the stack region 310 composed mostly of a peripheral circuit fill material, at least at elevations proximal to upper layers of the stack. The buttress structure 330 may comprise a material having a Young's modulus greater than the peripheral circuit fill material.

The device can comprise a 3D memory including the stack, through which a plurality of circuit elements, such as filled-trench vertical conductors, and a plurality of memory pillars (not shown) between pairs of the vertical conductors are disposed.

Prior to formation of openings such as elongated trenches in the stack used for forming the circuit elements 371 (vertical conductors), the buttress structure 330 is formed around the stack region 310.

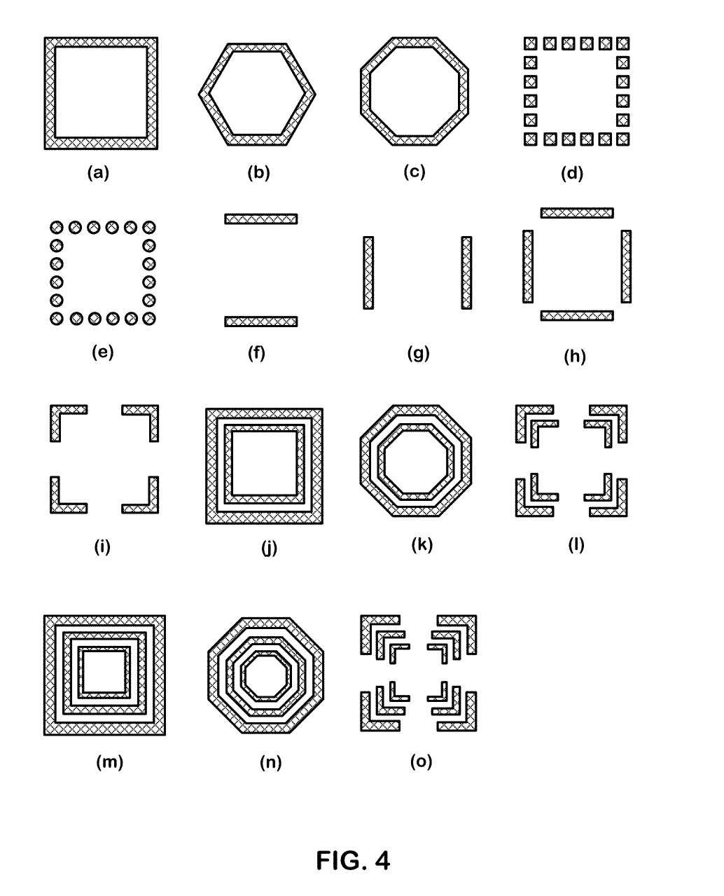

Depending on the layout or other design rules, the buttress structure may have, but is not limited to, the configurations and shapes as shown in FIG. 4. As illustrated in (a), (b), and (c) of FIG. 4, the fence-shaped, electrically passive element is a unitary closed polygonal element in various configurations disposed on a line surrounding the stack region. As illustrated in (d) and (e) of FIG. 4, the buttress structure includes a plurality of fence-shaped, electrically passive elements disposed in various configurations on a polygonal line surrounding the stack region. As illustrated in (f), (g) and (h) of FIG. 4, the buttress structure includes a plurality of fence-shaped, electrically passive elements in various configurations disposed on a polygonal line around the sides of the stack region. As illustrated in (i) of FIG. 4, the buttress structure includes a plurality of fence-shaped, electrically passive elements which are L-shaped, and disposed on corners of a polygonal line surrounding the stack region. As illustrated in (j)-(o) of FIG. 4, the buttress structure includes a plurality of fence-shaped, electrically passive elements in various configurations arranged on concentric lines surrounding the stack region.

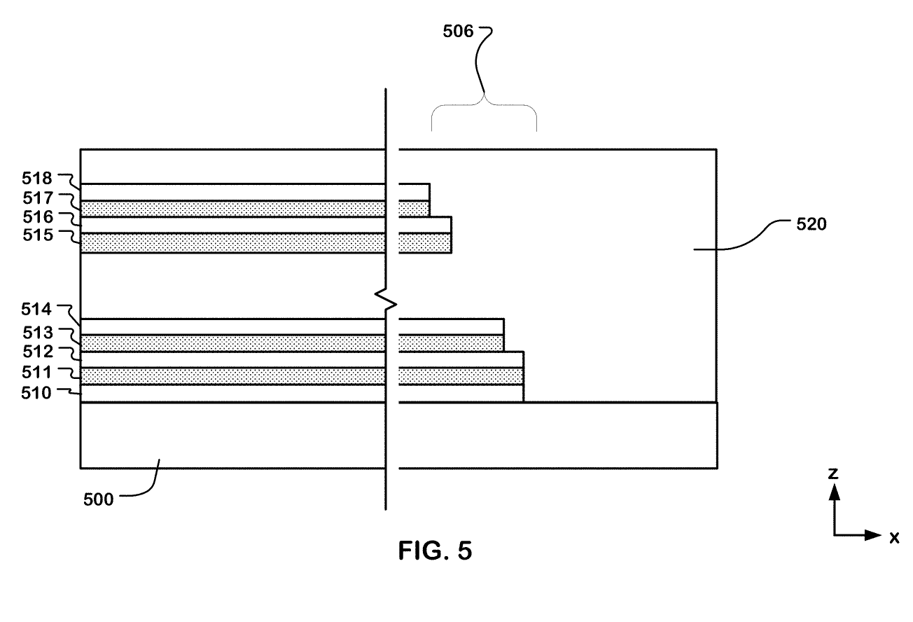

FIGS. 5 through 9 illustrate stages in an example process flow for manufacturing an integrated circuit comprising a vertical channel three-dimensional structure, included a buttress structure.

FIG. 5 is a cross-sectional view illustrating a structure in a manufacturing stage having a stack including a plurality of layers, including in the manufacturing stage represented by the figure, inactive insulating layers (e.g. 510, 512, 514, 516, 518) and sacrificial layers (e.g. 511, 513, 515, 517) over a substrate 500. The substrate 500 can include for example a bounded conductive plate on a die formed by a doping process, in which n-type or p-type doping materials are added to a semiconductor layer or bulk semiconductor to form a conductive region, or other underlying structure that supports the stack. The stack is formed in a stack region, called an array region for a memory device. The inactive insulating layers (e.g. 510, 512, 514, 516, 518) comprise an insulator such as silicon oxide, and the sacrificial layers (e.g. 511, 513, 515, 517) comprise a material that can be selectively etched relative to the insulator, such as silicon nitride in this example. An etch process is implemented to form a stair step structure in a region 506 on the perimeter of the stack in this example, configured in the 3D memory shown to provide word line landing pads. A fill material 520 is deposited covering the stack in the stack region and in a region outside the stack region over the substrate 300, followed by a planarization process, like chemical mechanical planarization (CMP) technique.

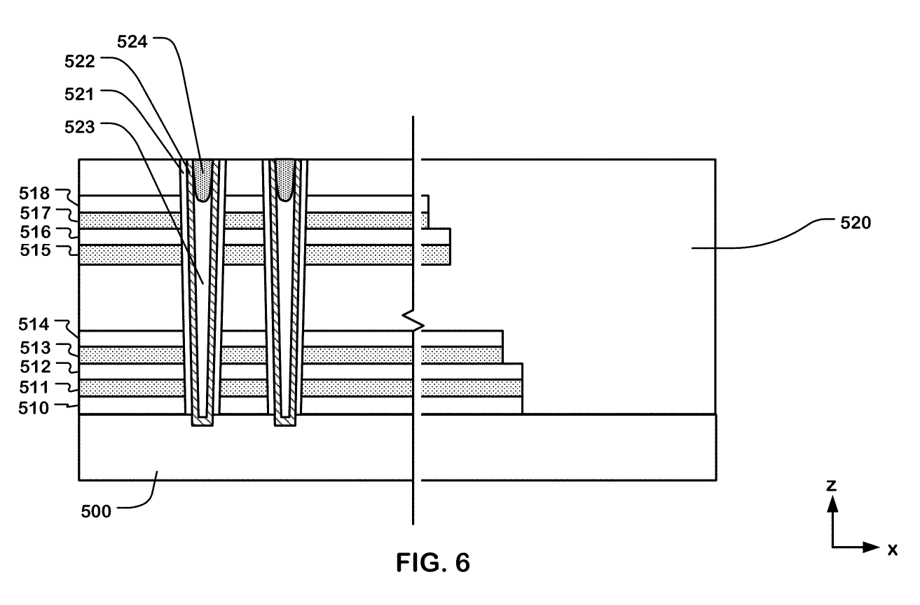

FIG. 6 is a cross-sectional view illustrating a structure in a subsequent manufacturing stage, having a plurality of vertical channel pillars in the stack. A hole etch is implemented to form a plurality of openings through the stack, followed by deposition of a memory layer 521 over the stack and within the openings in the plurality. The memory layer 521 can be a composite, multilayered film comprising a first layer configured as a blocking layer, a second layer configured as a charge trapping layer, and a third layer configured as a tunneling layer. The memory layer 521 has a conformal surface on the sidewalls and at the bottom of the openings in the plurality.

In one example, the memory layer comprises first, second and third layers. The first layer of the memory layer 521 is formed on the sidewalls of the openings and can comprise silicon oxide having a thickness of about 50 Å to 130 Å, and act as a blocking layer. Other blocking dielectrics can include high-κ materials like aluminum oxide of 150 Å.

The second layer of the memory layer 521 is formed on the first layer, and can comprise silicon nitride having a thickness of about 40 Å to 90 Å, and act as a charge trapping layer. Other charge trapping materials and structures may be employed, including, for example, silicon oxynitride (SiₓO_{y}N_{z}), silicon-rich nitride, silicon-rich oxide, trapping layers including embedded nano-particles and so on.

The third layer of the memory layer 521 is formed on the second layer and can comprise silicon oxide having a thickness of about 20 Å to 60 Å, and act as a tunneling layer. In another example, other tunneling materials and structures may be employed, for example, composite tunneling structure.

A composite tunneling structure can comprise a layer of silicon oxide less than 2 nm thick, a layer of silicon nitride less than 3 nm thick, and a layer of silicon oxide less than 4 nm thick. In one embodiment, the composite tunneling structure consists of an ultrathin silicon oxide layer O₁ (e.g. ≤15 Å), an ultrathin silicon nitride layer N₁ (e.g. ≤30 Å) and an ultrathin silicon oxide layer O₂ (e.g. ≤35 Å), which results in an increase in the valence band energy level of about 2.6 eV at an offset 15 Å or less from the interface with the semiconductor body. The O₂ layer separates the N₁ layer from the charge trapping layer, at a second offset (e.g. about 30 Å to 45 Å from the interface), by a region of lower valence band energy level (higher hole tunneling barrier) and higher conduction band energy level. The electric field sufficient to induce hole tunneling raises the valence band energy level after the second location to a level that effectively eliminates the hole tunneling barrier, because the second location is at a greater distance from the interface. Therefore, the O₂ layer does not significantly interfere with the electric field assisted hole tunneling, while improving the ability of the engineered tunneling dielectric to block leakage during low fields.

The deposition techniques applied to form the composite, multilayer film can be carried out by low-pressure chemical vapor deposition (LPCVD), atomic layer deposition (ALD), other suitable methods, or combinations.

Next, an etch process is carried out to remove the memory layer 521 on the top of the stack and at the bottom of the openings. A thin film 522 is then deposited over the stack and has a portion in contact with the substrate 500 at the bottom of the openings. The thin film 522 can comprise a semiconductor adapted by choice of material, e.g. silicon, and doping concentrations, e.g. undoped or lightly doped, to act as vertical channel structures.

After formation of the semiconductor thin film 522, a fill-in process is implemented using a spin-on dielectric (SOD), for example silicon oxide or other insulating materials, to fill the space between the thin film 522 within the openings, followed by a CMP process to remove the SOD on the top of the fill material 520 and an etch process to remove the SOD in the upper portions of the openings. So the insulating structures 523 are formed inside the pillars. In one example, the insulating structure 523 can be completely filled with the SOD, and be free of void and seam. In another example, a seam or a void may exist in the insulating structure 523.

Next, a conductive material, for example polysilicon, is deposited to fill the upper portions of the openings, followed by CMP and/or etch back processes to form the plugs 524, thereby providing contact areas for connections from the vertical channel pillars for vertical strings of memory cells, to the corresponding overlying patterned conductors (not shown). A salicide process is optionally applied to lower the resistance for better conductivity. In another example, the plugs 524 may comprise doped polysilicon.

In yet another example, the insulating structure 523 can be a seam or a gap, which is formed during the deposition of the thin film 522. The overhangs formed on the top of the inside surface of the thin film 522 may connect together so as to form the seam or gap enclosed by the thin film 522. The plugs 524 are therefore formed by the overhangs being connected.

In yet another example, the thin film 522 completely fills the openings in the stack, and therefore, the insulating structure 523 and the plugs 524 do not exist.

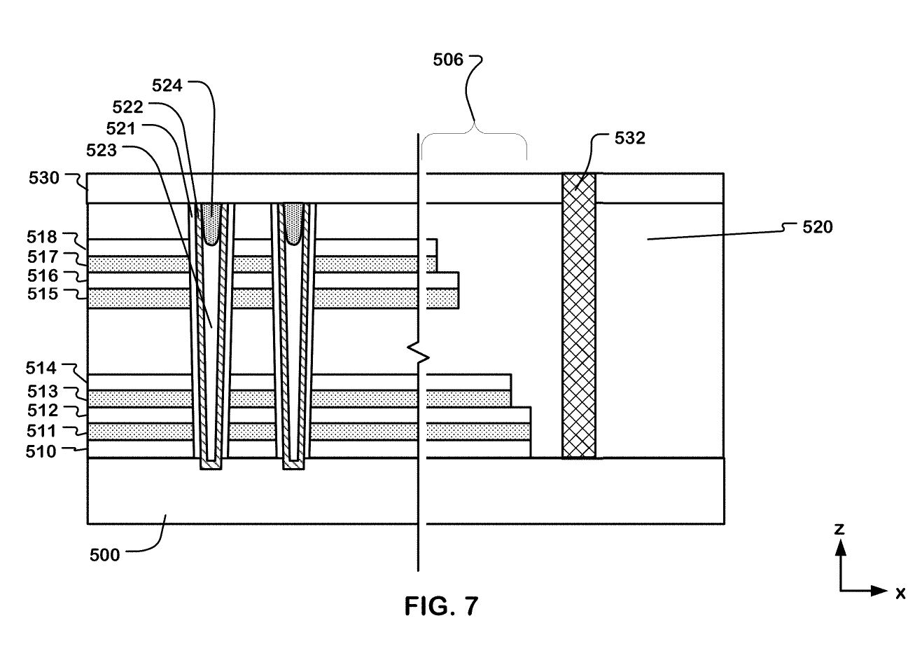

FIG. 7 is a cross-sectional view illustrating a structure in a further stage of the manufacturing process, forming a buttress structure 532 around the stack. In the process, a cap layer 530 comprising, for example, silicon oxide is deposited on the stack, followed by forming a patterned opening through the cap layer 530 and the fill material 520, and around the stack region in this embodiment. A fill-in process is then applied to fill the patterned opening so as to form a buttress structure 532 comprising a fence-shaped element disposed on a line around the stack. The material used for the buttress structure preferably has a Young's modulus greater than the fill material 520, thereby opposing expansion in a direction toward the stack region of materials outside the stack region that tends to impose deformation stress on the stack structure. The buttress structure 532 can comprise fence-shaped elements of polysilicon, tungsten, silicon nitride, silicon oxynitride, combinations thereof, or other materials disposed in the fill material 520 surrounding the stack region. As illustrated, the structure in the region outside the stack region (outside the stair step structure in region 506) comprises circuit elements of the peripheral circuits (not shown) and consists mostly of fill material, such as fill material 520 and other fill materials used in the manufacturing of the peripheral circuits, at least at elevations proximal to upper layers of the stack, or for the purposes of a specific benchmark, at least at elevations including the upper half of the layers in the stack.

Using a material with a greater Young's modulus than the fill material used in the peripheral circuits, or in the region in which the buttress is formed, results in a buttress structure more rigid than the fill material, and will resist deformation in the stack by the thermal expansion of materials outside the buttress structure in the following manufacturing processes.

In some embodiments, the buttress structure can comprise a gap, alone or in combination with a fence-shaped element or elements, at least during stages of the manufacturing process in which the stress is to be offset by the buttress structure, which allows the device to have more space to absorb the thermal expansion.

The buttress structure 532 can extend into the fill material 520 to a depth at an elevation proximal to the bottom layer of the stack, such that the buttress structure 532 is in contact with the substrate. In some embodiments, the buttress structure 532 can have a depth at an elevation proximal to the intermediate layer of the stack and does not contact the substrate 500.

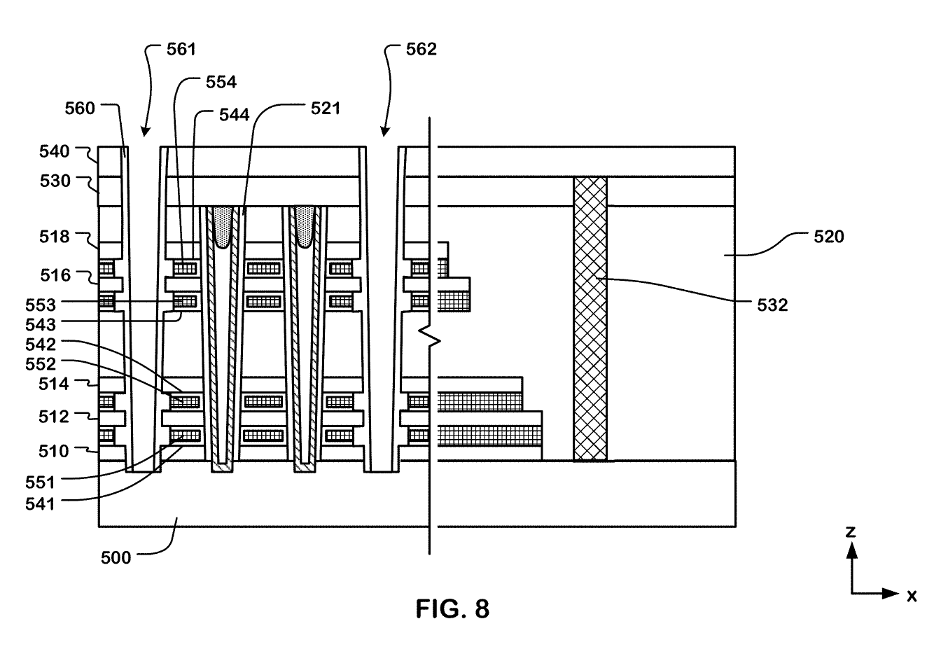

FIG. 8 is a cross-sectional view illustrating a structure in a further manufacturing stage, forming active layers comprising a conductive material in place of the sacrificial layers in the stack. In the process, another oxide film 540 is deposited over the stack, followed by etching through the plurality of layers in the stack to form a pattern of openings (e.g. 561, 562) in the stack. The openings (also called trenches) extending in the stack can be greater than 1 μm deep, up to 8 μm for example, and greater than 0.1 μm wide, up to 0.8 μm for example. As such, the openings have an aspect ratio of 10 or more. As a result of formation of the openings, the stack becomes susceptible to deformation due to expansion stress. The buttress structure resists the expansion stress at this stage of the process, protecting the accuracy of the pattern of openings.

Next, in this example a gate replacement process is implemented which can further increase the susceptibility of the stack to deformation stresses. The gate replacement process in this example comprises (1) removing the sacrificial layers (e.g. 511, 513, 515, 517 of FIG. 7) in the stack using phosphoric acid (H₃PO₄) to expose the surface of the inactive layers (silicon oxide) and the surface of the memory layer, (2) forming a thin layer (e.g. 541, 542, 543, 544) of high-κ material like aluminum oxide on the exposed surface of the inactive insulating layers (e.g. 510, 512, 514, 516, 518) in the stack and on the exposed surface of the memory layer 521, and (3) depositing a conductive material in voids between the inactive insulating layers to form active layers alternating with the inactive insulating layers. The conductive material can comprise tungsten (W), tungsten nitride (WN), tantalum (Ta), tantalum nitride (TaN), titanium (Ti), titanium nitride (TiN), or the combinations thereof. A wet etch is then applied to remove the conductive material on the sidewalls and at the bottom of the openings, thereby forming recesses on the sidewalls of the openings.

After the gate replacement process, the stack comprises active layers consisting of active circuit elements such as the metal gates (e.g. 551, 552, 553, 554). The memory cells are disposed at the interface regions between the active layers and the pillars. In this embodiment, the active layers acts as the word lines surround the pillar and constitutes the all-around gates. The memory cells have gate-all-around configuration.

Next, an insulator 560 is deposited covering the sidewalls of the openings (e.g. 561, 562) and filling the recesses on the sidewalls. In one example, the insulator 560 is formed at a low temperature, for example 25° C. to form an oxide layer. In another example, the insulator 560 can comprise materials other than silicon oxide and be formed using other deposition techniques, such as CVD, ALD, and PVD. Then, an etch process is applied to remove the insulator 560 at the bottom of the elongated trenches.

An anneal process up to a temperature about 1000° C., for example, is implemented to solidify the insulator 560. The high temperature tends to cause thermal expansion and induce deformation. The buttress structure 532 formed prior to the anneal process would oppose expansion of materials outside the stack region in a direction toward the stack region.

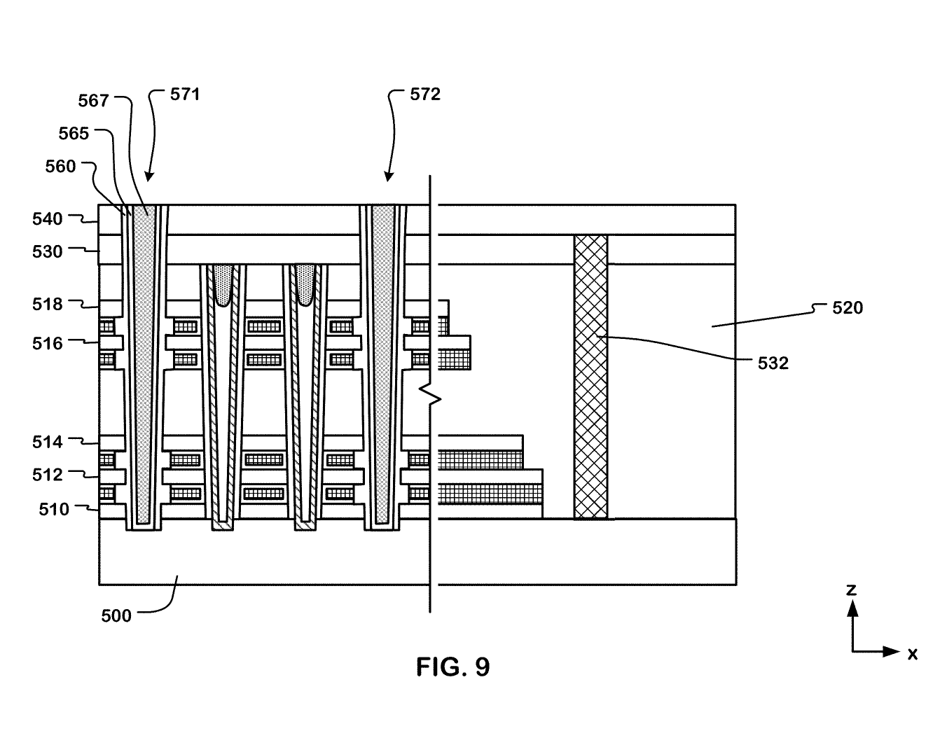

FIG. 9 is a cross-sectional view illustrating a structure in a further manufacturing stage, in which at least some of the openings in the stack are filled with conductive or semiconductive material to form circuit elements 571, 572 in the stack. The circuit elements 571, 572 are in the form of vertical conductors in this example, extending through the plurality of layers (active and inactive layers) in the stack region. In the process, a barrier layer 565 is deposited over the stack using CVD, PVD, or ALD to form a layer of about 30 Å to 1000 Å thick. An annealing process is then optionally applied to the deposited barrier layer 565. A conducting layer 567 is then deposited using CVD, PVD, ALD, electroplating (EP) or other deposition techniques to fill the openings. In this example, the conducting layer 567 completely fills the openings. Then, a CMP process is applied to remove the barrier layer 565 and the conducting layer 567 on the top of the oxide film 540. In other embodiments, during the CMP process, the oxide film 540 is optionally removed to expose the buttress structure 532.

The material suitable for the barrier layer 565 of the circuit elements (e.g. 571, 572) in form of the vertical conductor in this example may comprise silicon nitride (SiN), Titanium (Ti), titanium nitride (TiN), tungsten nitride (WN), tantalum (Ta), tantalum nitride (TaN), other metal alloys, or combinations thereof.

The material suitable for the conducting layer 567 of the circuit elements (e.g. 571, 572) in form of the vertical conductor in this example may comprise polysilicon, amorphous silicon, Titanium (Ti), titanium nitride (TiN), tungsten (W), tungsten nitride (WN), tantalum (Ta), tantalum nitride (TaN), aluminum (Al), copper (Cu), cobalt (Co), other metals and metal alloys, or combinations thereof.

In another embodiment, the barrier layer 565 can be omitted where the conductive layer 567 comprises for example polysilicon or other materials, which can provide good adhesion between the insulator 560 and the conducting layer 567.

A first plurality of patterned conductors (not shown) overlying the stack is connected by interlayer conductors through vias aligned with the circuit elements 571, 572 (i.e. vertical conductors in this example) and to a source of a reference voltage, configured as a common source line. As such, an electrical conductor over the stack is connected to one or more of the circuit elements. Also, a second plurality of patterned conductors (not shown) overlying the stack connects the plurality of pillars to a voltage supply, providing bit line voltages to the corresponding vertical channel structures of the pillars, configured as bit lines. In addition, a third plurality of patterned conductors (not shown) overlying the stack is connected to the corresponding active layers through contacts in the stair step structure (word line landing pad), configured as word lines. The patterned conductors and interlayer conductors in the vias can be formed by aligning a mask with one or more of the circuit elements in the stack; and using the aligned mask, making an electrical conductor over the stack connecting to the one or more of the circuit elements in the stack. Because of the use of the buttress structure before forming the openings used for the circuit elements 571, 572 (vertical conductors), the alignment can be accomplished with greater accuracy, allowing for denser circuit structures.

The process includes forming control circuitry in the peripheral region outside the stack region, configured to apply different bias voltages to the active layers and pillars in the stack, and can be configured to execute a program operation by which one, or more than one, bit of data can be stored in a selected memory cell.

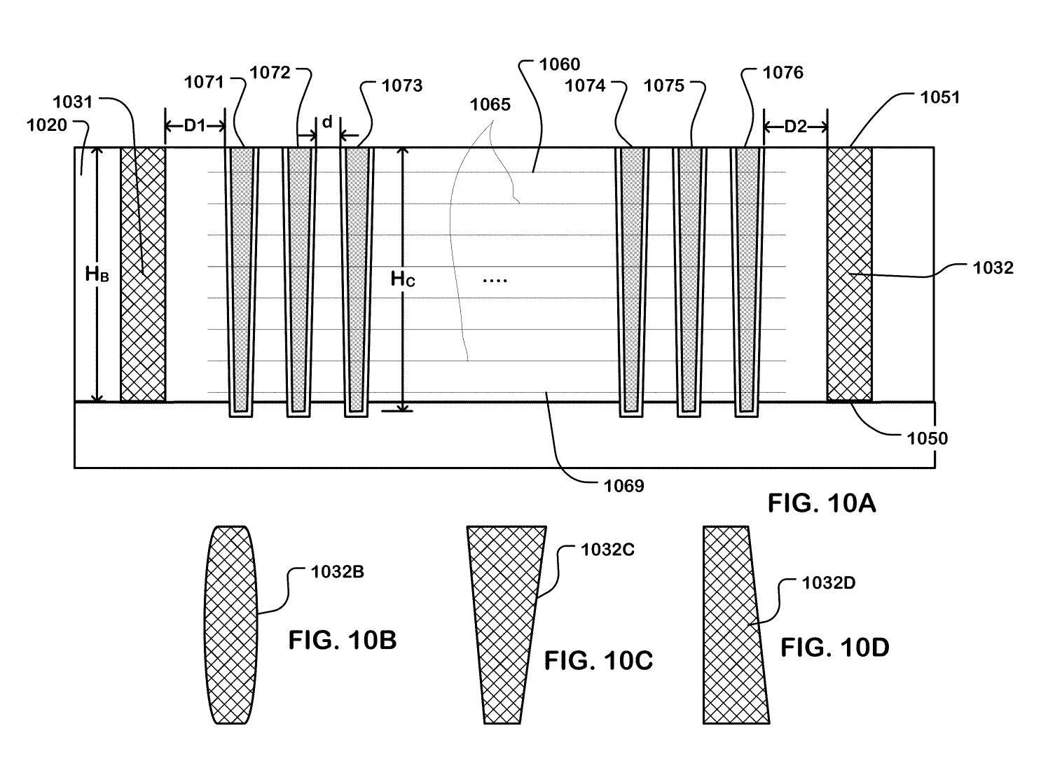

FIG. 10A illustrates a simplified cross-sectional view of the memory device in FIG. 3 taken at A-A′. In the illustration, the stack (bottom active layer 1069, top active layer 1060 and intermediate active layers 1065) and the plurality of pillars in the stack are not shown for a clear view. In the array, the distance between the vertical conductors (e.g. 1071, 1072, 1073, 1074, 1075, 1076) is denoted as d and is about 0.6 μm. The buttress structure 1032 has a width about 0.15 μm at a top surface 1051 in this example. The distance D1 between the buttress structure 1031 and the leftmost vertical conductor 1071 can be equal to or greater than the distance d between the vertical conductors. Likewise, the distance D2 between the buttress structure 1032 and the rightmost vertical conductor 1076 can be equal to or greater than the distance d between the vertical conductors. The distances D1 and D2 can be the same or different. The distances D1 and D2 range from 0.6 μm to several hundred microns.

In other examples, the buttress structure in the cross-section can be bowed (e.g. structure 1032B in FIG. 10B), trapezoidal (e.g. structure 1032C in FIG. 10C), tapered (e.g. structure 1032D in FIG. 10D) or have other shaped profiles.

The depth (H_{B}) of the buttress structure is defined for the purposes of this description by the elevation of a lower surface 1050 relative to the bottom active layer in the stack. The lower surface 1050 is at an elevation less than the depth (Hc) of the vertical conductors in the illustrated example, and below the bottom active layer. The buttress structure can have a depth (H_{B}) so that the lower surface 1050 is at a minimum depth as low as one tenth of the height of the stack and less than one tenth the thickness of the fill material 1020. The depth (H_{B}) of the buttress structure can be greater than the depth (Hc) of the vertical conductors in the other embodiments.

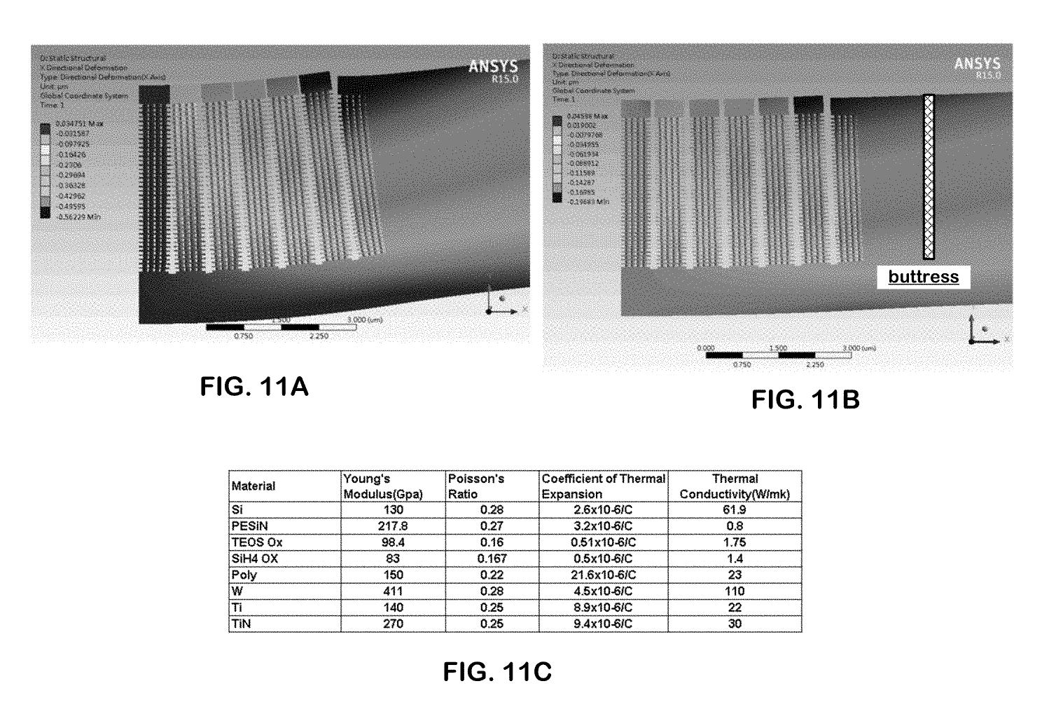

FIGS. 11A and 11B are graphs showing simulation results using ANSYS software for 3D memories without and with the buttress structure, respectively. FIG. 11C is a table showing the parameters for different materials applied to the ANSYS simulations of FIGS. 11A and 11B. In the simulation, silicon (Si) is used for the substrate (e.g. 500 of FIG. 9); plasma-enhanced silicon nitride (PESIN) is used for the sacrificial layers; SiH₄ oxide is used for the fill material (e.g. 520 of FIG. 9); TEOS is used for the inactive insulating layer in the stack (e.g. 510, 512, 514, 516, 518 of FIG. 9); silicon oxide is used for the insulating layer on the sidewall (e.g. 560 of FIG. 9); polysilicon (Poly) is used for the buttress structure (e.g. 532 of FIG. 9); Ti/TiN is used for the barrier layer (e.g. 565 of FIG. 9); tungsten (W) is used for the conducting layer (e.g. 567 of FIG. 9). In FIG. 11A, the structure includes trenches through a stack about 3 microns deep at a stage after removal of sacrificial layer material in a gate replacement process as described above. The simulation shows a maximum displacement of 562 nm at the trench for the outermost vertical conductor, where there is no buttress structure. In FIG. 11B, the structure includes trenches about 3 microns deep at a stage after removal of sacrificial layer material in a gate replacement process as described above. The simulation shows the displacement of the trench for the outermost vertical conductor decreases to 193 nm, where the buttress structure exists to oppose expansion of materials outside the array region in a direction toward the array region. In the simulation, the buttress structure is filled with polysilicon and has a rectangular shape.

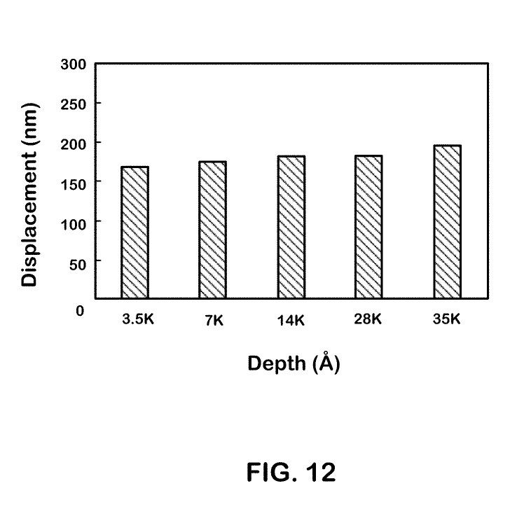

FIG. 12 is a bar chart illustrating the displacement as a function of the depth of the buttress structure. The data are collected based on the ANSYS simulation as described in FIG. 11B. In the simulation, the maximum depth of the buttress structure is 3.5 μm (35 KÅ), which is the thickness of the fill material (e.g. 1020 of FIG. 10) and greater than the height of the stack as measured from the lower surface of the bottom active layer to the upper surface of the top active layer, and the minimum depth is 0.35 μm (3500 Å), less than 15% of the height of the stack. The simulation results show that the shorter depth of the buttress structure exhibits a bit less displacement. So the buttress structure can have a depth less than the height of the stack, and can have a lower surface above the bottom layer of the stack, at an elevation proximal to an intermediate layer of the stack.

In one embodiment, the buttress structure comprises a higher Young's modulus material than the fill material in which it is disposed, to increase the rigidity of the structure and to diminish the deformation.

In another embodiment, the buttress structure comprises a gap alone or in combination with a solid material, to create space to absorb the thermal expansion so as to release the stress and diminish the deformation.

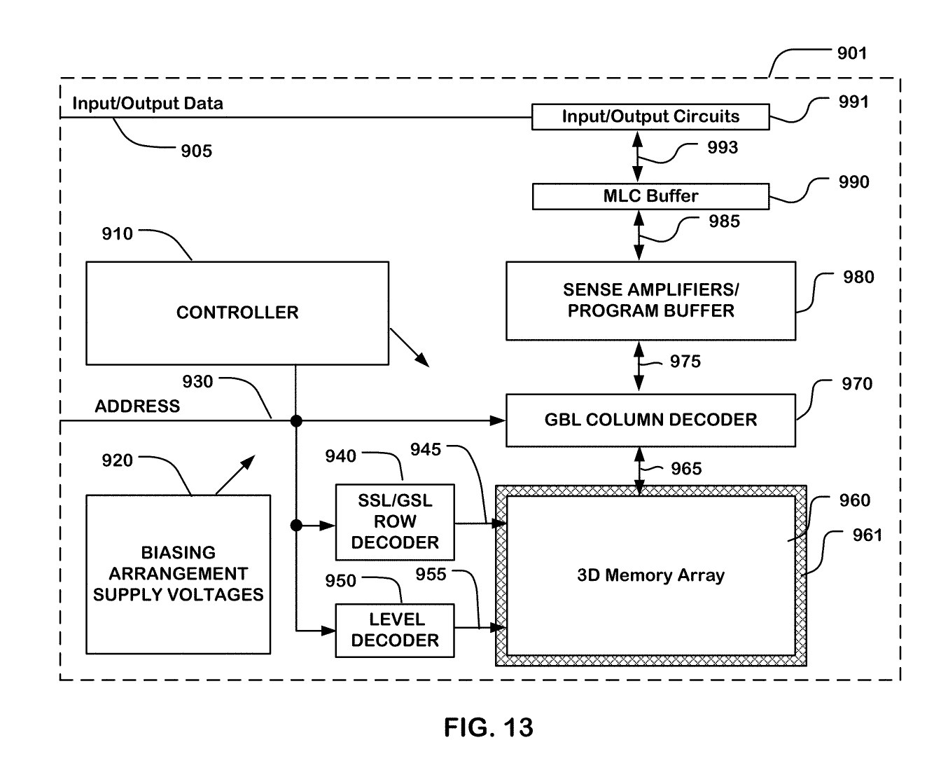

FIG. 13 is a simplified chip block diagram of an integrated circuit 901 including a 3D, vertical thin-channel film NAND array. The integrated circuit 901 includes a 3D memory array 960 including one or more memory blocks having the buttress structure 961 as described herein.

An SSL/GSL decoder 940 is coupled to a plurality of SSL/GSL lines 945, arranged in the memory array 960. A level decoder 950 is coupled to a plurality of word lines 955. A global bit line column decoder 970 is coupled to a plurality of global bit lines 965, arranged along columns in the memory array 960 for reading data from and writing data to the memory array 960. Addresses are supplied on bus 930 from control logic 910 to decoder 970, decoder 940 and decoder 950. Sense amplifier and program buffer circuits 980 are coupled to the column decoder 970, in this example via first data lines 975. The program buffer in circuits 980 can store program codes for multiple-level programming, or values that are a function of the program codes, to indicate program or inhibit states for selected bit lines. The column decoder 970 can include circuits for selectively applying program and inhibit voltages to bit lines in the memory in response to the data values in the program buffer.

Sensed data from the sense amplifier/program buffer circuits 980 are supplied via second data lines 985 to multi-level data buffer 990, which is in turn coupled to input/output circuits 991 via a data path 993. Also, input data is applied in this example to the multi-level data buffer 990 for use in support of multiple-level program operations for each of the independent sides of the independent double gate cells in the array.

Input/output circuits 991 drive the data to destinations external to the integrated circuit 901. Input/output data and control signals are moved via data bus 905 between the input/output circuits 991, the control logic 910 and input/output ports on the integrated circuit 901 or other data sources internal or external to the integrated circuit 901, such as a general purpose processor or special purpose application circuitry, or a combination of modules providing system-on-a-chip functionality supported by the memory array 960.

In the example shown in FIG. 13, control logic 910, using a bias arrangement state machine, controls the application of supply voltages generated or provided through the voltage supply or supplies in block 920, such as read, erase, verify and program bias voltages. The control logic 910 is coupled to the multi-level data buffer 990 and the memory array 960. The control logic 910 includes logic to control multiple-level program operations. In embodiments supporting the Gate-All-Around (GAA) NAND structures described herein, the logic is configured to perform the method of:

applying a reference voltage to common source lines, such as biasing the conductive layer on the substrate via the vertical conductors described herein;

selecting a layer of memory cells in the array, such as using a word line layer decoder;

selecting vertical channel structures in a selected row in the array such as by using SSL switches and GSL switches on the rows of vertical channel structures; and

storing charge in charge trapping sites in the selected layer on the selected row of vertical channel structures in the array, to represent data using bit line circuitry like page buffers on global bit lines coupled to the selected row of vertical channel structures.

In some embodiments, the logic is configured to select a layer, such as by controlling word line layer decoders.

In some embodiments, the logic is configured to store multiple levels of charge to represent more than one bit of data in the charge trapping sites in the selected layer on the selected row of vertical channel structures in the array. In this manner, a selected cell in the array stores more than two bits, including more than one bit on each cell.

The control logic 910 can be implemented using special-purpose logic circuitry as known in the art. In alternative embodiments, the control logic comprises a general-purpose processor, which can be implemented on the same integrated circuit, which executes a computer program to control the operations of the device. In yet other embodiments, a combination of special-purpose logic circuitry and a general-purpose processor can be utilized for implementation of the control logic.

The buttress structure described herein can be implemented in other 3D structures and circuits, and in other complex structures.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims. What is claimed is:

1. An integrated circuit comprising:
a stack region and a region outside the stack region over a substrate;
a stack including a plurality of layers disposed in the stack region;
a plurality of circuit elements extending through the stack; and
a buttress structure disposed around the stack region within the region outside the stack region, the buttress structure comprising a fence-shaped, electrically passive element outside of the stack region configured to oppose expansion of materials in the region outside the stack region in a direction toward the stack region.

2. The integrated circuit of claim 1, comprising a structure in the region outside the stack region that is composed mostly of a fill material at least at elevations proximal to upper layers of the stack, wherein the buttress structure is disposed in the fill material and comprises a material having a Young's modulus greater than the fill material.

3. The integrated circuit of claim 1, wherein the buttress structure is isolated from ground potential.

4. The integrated circuit of claim 1, wherein the plurality of layers includes a top layer, a bottom layer, and a plurality of intermediate layers between the top and bottom layers, and the buttress structure has a lowest surface at an elevation higher than the bottom layer of the stack.

5. The integrated circuit of claim 1, wherein the fence-shaped, electrically passive element is a unitary closed polygon surrounding the stack region.

6. The integrated circuit of claim 1, wherein the buttress structure comprises a plurality of fence-shaped, electrically passive elements disposed on a polygonal line surrounding the stack region, including said first-mentioned fence-shaped, electrically passive element.

7. The integrated circuit of claim 1, wherein the buttress structure comprises a plurality of fence-shaped, electrically passive elements arranged on concentric lines around the stack region, including said first-mentioned fence-shaped, electrically passive element.

8. The integrated circuit of claim 1, wherein the buttress structure comprises a plurality of fence-shaped, electrically passive elements which are L-shaped and disposed on corners of a polygonal line surrounding the stack region, including said first-mentioned fence-shaped, electrically passive element.

9. A method of manufacturing an integrated circuit comprising:
forming a stack including a plurality of layers in a stack region on a substrate;
forming a buttress structure around the stack, the buttress structure comprising a fence-shaped, electrically passive element configured to oppose expansion of materials in a region outside the stack region in a direction toward the stack region;
etching through the plurality of layers in the stack to form a pattern of openings in the stack, after forming the buttress structure; and
filling at least some of the openings in the stack with conductive or semiconductive material to form circuit elements in the stack.

10. The method of claim 9, further comprising:
aligning a mask with one or more of the circuit elements in the stack; and
using the aligned mask, making an electrical conductor over the stack connecting to the one or more of the circuit elements in the stack.

11. The method of claim 9, wherein:
the plurality of layers includes sacrificial layers and inactive insulating layers in the stack;
said etching includes forming a plurality of openings through the stack after said forming the buttress structure; and
removing portions of the sacrificial layers in the stack and depositing a conductive material in voids between the inactive insulating layers in the stack.

12. The method of claim 11, further comprising:
filling a conductive material in the plurality of openings to form circuit elements comprising vertical conductors extending through the stack.

13. The method of claim 9, further comprising forming a structure in a region outside the stack that is composed mostly of a fill material at least at elevations proximal to upper layers of the stack, wherein the buttress structure comprises a material having a Young's modulus greater than the fill material.

14. The method of claim 9, wherein the buttress structure is isolated from ground potential.

15. The method of claim 9, wherein the buttress structure has a depth less than a height of the stack.

16. The method of claim 9, wherein the buttress structure comprises a fence-shaped, electrically passive element configured in a closed polygon surrounding the stack region.

17. The method of claim 9, wherein the buttress structure comprises a plurality of fence-shaped electrically passive elements arranged on concentric lines surrounding the stack region.

18. The method of claim 9, wherein the buttress structure comprises a plurality of fence-shaped, electrically passive elements which are L-shaped and disposed on corners of a polygonal line surrounding the stack region.

19. An integrated circuit comprising:
a stack of active and inactive layers disposed over a substrate;
a plurality of vertical conductors extending through the stack of active and inactive layers; and
a region surrounding the stack including a buttress structure in a fill material outside of the stack, wherein the buttress structure comprises a material having a Young's modulus greater than the fill material.

20. The integrated circuit of claim 19, wherein the buttress structure comprises a fence-shaped, electrically passive element configured to oppose expansion of materials outside the stack in a direction toward the stack.
